(19) United States
(12) Patent Application Publication
(10) Pub. No.: US 2002/0179987 A1
(43) Pub. Date: Dec. 5, 2002

(54) Electronic control circuit

(76) Inventors: Marcus Meyer, Karlsbad (DE); Stefan Reck, Ettlingen (DE); Stefan Kotthaus, Sinzheim (DE); Joerg Wolf, Karlsruhe (DE); Michael Soellner, Lichtenau (DE)

Correspondence Address: Striker Striker & Stenby, 103 East Neck Road, Huntington, NY, 11743, US

(21) Appl. No.: 09/959,141

(22) PCT Filed: Jan. 31, 2001
(86) PCT No.: PCT/DE01/00358

(30) Foreign Application Priority Data
Feb. 21, 2000 (DE) 100 07 868.0

(51) Int. Cl. H01L 43/06

(52) U.S. Cl. 257/427; 361/783; 257/696; 257/778; 257/690

(57) ABSTRACT

The invention is based on an electronic control circuit (10) having a printed circuit board (12) on which multiple electronic components (14, 16, 18, 20, 22) are arranged, in at least one (18) of which a Hall-effect sensor (20, 22) having a circuit part (18) belonging to the control electronics is assembled.

It is proposed that the Hall-effect sensor (20, 22) is situated on a silicon chip (48, 50) and its active surface (52) is situated at a minimal distance (68) from a magnetic flux sensor (38) that can be moved relative to the Hall-effect sensor (20, 22).

### RELATED ART

The invention is based on an electronic control circuit according to the preamble of Claim 1.

Electronically activated positioning motors are used in the automotive industry for a variety of different applications. When used as a window lifter or a sunroof motor, in particular, it is necessary to situate an electronic control circuit with a sensor for angles of rotation, e.g., a Hall-effect sensor, on-site in order to implement functions such as protection against pinching. Legal regulations will place greater demands on sensor technology in the future in order to ensure that any instance in which pinching could occur is reliably detected and prevented. This requires a higher number of poles of a magnetic flux sensor designed as ring magnets. When a higher number of poles is used, however, the magnetic field becomes weaker and more difficult to detect using sensors.

A device for detecting the angle of rotation, the speed and/or direction of rotation of a rotary operating mechanism is made known in DE 195 25 292 A1. A permanent magnet is situated on a printed circuit board in the electronics chamber of an electric motor. The two poles of the magnet are connected with magnetic flux conductors that lead to the armature shaft of the electric motor situated at a distance from the electronics chamber where one end section each of the magnetic flux conductor is situated at a minimal distance from a magnetic flux sensor moved with the armature shaft. The magnetic flux sensor comprises ferromagnetic and diamagnetic sections arranged on a float. It rotates with the armature shaft, which causes the magnetic flux in a magnetic circuit formed by the permanent magnet, the magnetic flux conductor, and the magnetic flux sensor to change. A Hall-effect sensor situated on the printed circuit board over the permanent magnet detects the change in the magnetic field of the changing stray field and generates an electric output signal as a function of the change. This is fed to a control unit, e.g., a microcontroller. The known control circuit takes up a great deal of space and, due to the numerous individual parts and their arrangement with regard for each other, contains many manufacturing tolerances that have a negative effect on safety and control quality.

Moreover, a sensor device is made known in DE 197 39 682 A1 that comprises a stationary magnetic field sensor designed as a Hall-effect sensor that is magnetically coupled with at least one stationary magnetic flux conductor that detects a variable magnetic field and feeds it to the Hall-effect sensor. This generates an electric output signal as a function of the change in the magnetic field for an electronic control unit. Two Hall-effect sensors situated at a distance from each other can be provided, at least one of which has at least one part of an electronic control circuit assembled as a customized, integrated circuit situated in an electronic component. This component is positioned on a printed circuit board at a distance from a magnetic flux sensor and is situated between the end sections of at least two magnetic flux conductors. Although the printed circuit board and the components arranged on it have a greater integration level, numerous manufacturing tolerances also occur as a result.

### ADVANTAGES OF THE INVENTION

According to the invention, the Hall-effect sensor is situated on a silicon chip that contains a circuit part belonging to the control electronics, e.g., a control unit, whereby the active surface of the Hall-effect sensor is situated at a minimal distance from a magnetic flux sensor that can be moved relative to the Hall-effect sensor, e.g, from a ring magnet. By integrating the Hall-effect sensors on a silicon chip of the control unit, external Hall-effect sensors can be eliminated, which results in a lower number of components and, therefore, a smaller printed circuit board. Moreover, situating the small printed circuit board directly next to the magnetic flux sensor eliminates the need for magnetic flux conductors, which also reduces the number of components and the amount of space required.

The silicon chip can be advantageously situated in a housing and bonded to circuit-board conductors of the printed circuit board by way of connecting pins via soldering, whereby the active surface of the Hall-effect sensor advantageously lies on the side of the silicon chip facing the magnetic flux sensor, so that the distance between the magnetic flux sensor and the active surface of the Hall-effect sensor is determined—apart from the positional tolerances of the printed circuit board—only by the tolerances of the housing of the component and the brazing seam between the circuit-board conductor and the connecting pins. A very small distance can therefore be realized, which is particularly important for the precise and reliable detection of weak magnetic fields.

According to an embodiment of the invention, the silicon chip is bonded as a flip-chip to the printed circuit board, whereby the active surface of-the Hall-effect sensor is situated on the bonding side of the silicon chip and faces away from the magnetic flux sensor. Since the thickness of the silicon chip is smaller than the normal distance between the top surface of the upper edge of the housing in enclosed assemblies, the distance between the active surface of the Hall-effect sensor and the magnetic flux sensor can be further reduced. Moreover, the thickness of the silicon chip can be determined with great accuracy in semiconductor production, and the height of the soldered joints between the silicon chip and the circuit-board conductors—the “bumps”—is subjected to relatively minimal scattering, so that the distance between the surface of the printed circuit board and the active surface of the Hall-effect sensor is determined much more accurately in the chain of tolerances. The active surface of the Hall-effect sensor can therefore be placed closer—and with greater precision—to the magnetic flux sensor, and even weaker magnetic fields can be detected with a high degree of reliability.

Moreover, with flip-chip technology, the silicon chip is applied to the printed circuit board in a reflow soldering process, whereby self-centering takes place in a process of floating into position when the solder is melted on. As a result, the horizontal as well as the lateral tolerance is improved as compared with bonding using connecting pins. Moreover, since a housing is eliminated and the silicon chip is embedded with the soldered joints in a sub-layer instead, the silicon chip—including the sub-layer—takes up much less space than a component having a housing, which enables the printed circuit board to be designed to be smaller and less expensive.

Two Hall-effect sensors situated at a distance from each other are usually required to detect the angle of rotation. Since the silicon chip is large enough for the control unit and it is larger than silicon chips for separate Hall-effect sensors, a relatively great distance between the Hall-effect sensors can be selected without requiring any additional silicon surface area. The distance can therefore be advantageously adapted to the respective application.

### DIAGRAM

Further advantages result from the following description of the diagram. The diagram presents embodiments of the invention. The drawing, the description, and the claims contain numerous features in combination. It is advantageous for the expert to also examine the features individually and combine them into additional logical combinations.

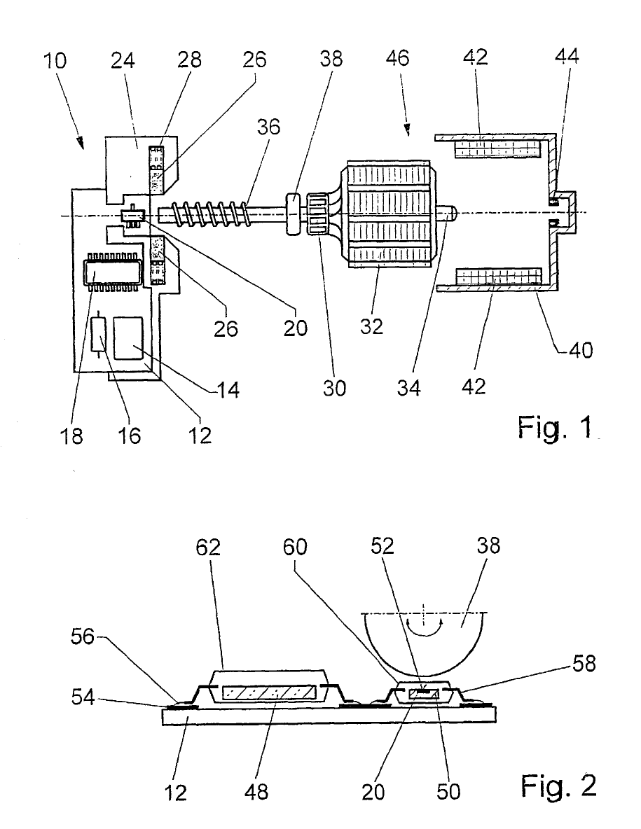

FIG. 1 shows an electric positioning motor according to the related art in an exploded diagrammatic view,

FIG. 2 shows a partial cross section through the region of a Hall-effect sensor according to FIG. 1,

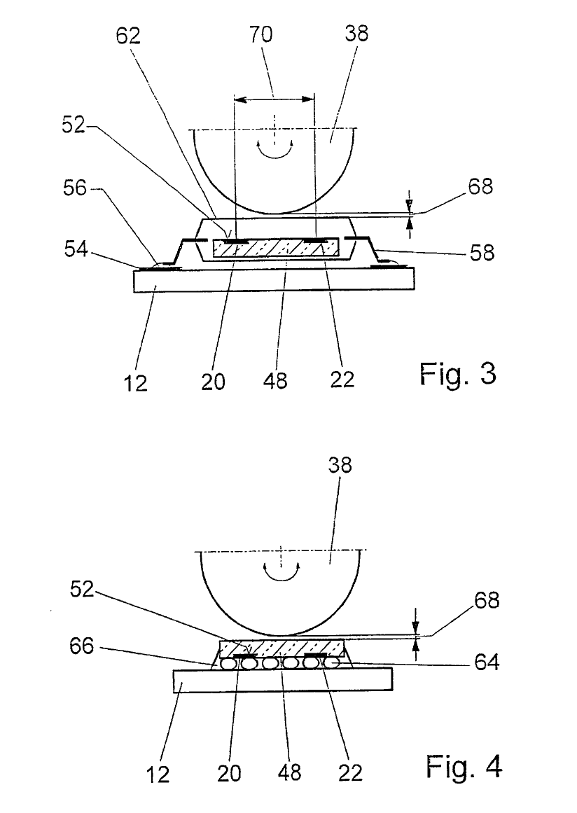

FIG. 3 shows a cross section according to FIG. 2 through a control circuit according to the invention, and

FIG. 4 shows a variant according to FIG. 3.

### DESCRIPTION OF THE EMBODIMENTS

A positioning motor 46 according to the related art comprised a field frame 40 having multiple magnets 42, an armature 32, the armature shaft 34 of which is supported in rotary fashion in the field frame 40 by way of a bearing, and carries a worm gear 36 on its exposed end, a brush holder 24 with brushes 26 that are pressed against a commutator 10 of the armature 32 by springs 28, and a control circuit 10. The control circuit 10 comprises a printed circuit board 12 that carries discrete components in the form of an output module 14, a control unit 18 and/or Hall-effect sensors 20, 22, and other components 16. The Hall-effect sensors 20, 22 comprise active surfaces 52 on a silicon chip 50 that interact with a magnetic flux sensor in the form of a ring magnet 38 that sits on the armature shaft 34 between the commutator 30 and the worm gear 36.

In the known control circuit according to FIG. 1, the Hall-effect sensor 20 is situated on the silicon chip 50 that is situated in a separate housing 60 and is soldered to a circuit-board conductor 54 of the printed circuit board 12 in a brazing seam 56 by way of connecting pins. Such a control circuit 10 is very expensive and takes up a great deal of space; large printed circuit boards 12 are required in particular. Moreover, multiple Hall-effect sensors 20, 22 can be situated on the silicon chip at very small distances from each other if the size of the space may not be increased.

In the embodiments according to the invention and shown in FIGS. 3 and 4, the Hall-effect sensors 20, 22 are situated on the silicon chip 48 of a control unit 18. As a result of the integration, separate Hall-effect sensors are eliminated, so the printed circuit board 12 can be designed to be smaller in size. Moreover, the Hall-effect sensors 20, 22 can be situated on the silicon chip 48 at a greater distance 70 from each other, because the silicon chip 48 for the control unit 18 is relatively large by nature, so that the distance 70 can be adapted with wide limits to the actual application without taking up additional silicon surface area.

In a component design according to FIG. 3 having a housing 62, the Hall-effect sensors 20, 22 are situated on the side of the silicon chip 48 facing the magnetic flux sensor 38. As a result, with a small air gap 68 between the surface of the housing 62 and the magnetic flux sensor 38, a minimal distance can be maintained between the active surface 52 of the Hall-effect sensors 20, 22 and the ring magnet 38, whereby only the tolerances of the brazing seam 56 and the housing 62 to the positional tolerances of the printed circuit board 12 need to be taken into consideration.

In the embodiment according to FIG. 4, the housing 62 is eliminated, and the silicon chip 48 is bonded as a flip-chip on the printed circuit board 12 by way of soldered joints 64. In this case, the Hall-effect sensors 20, 22 are situated on the bonding side of the silicon chip 48, whereby the active surfaces 52 face away from the ring magnet 38. The distance between the active surface 52 and the ring magnet 38 is determined by the thickness of the silicon chip 48 and the air gap 68, whereby the thickness of the silicon chip 48 can be produced with very small tolerances in semiconductor production. The air gap 68 is determined in particular by the positional tolerances of the printed circuit board 12 and the thickness tolerances of the soldered joints.

The silicon chip 48 is embedded with its soldered joints 64 in an insulating sub-layer 66. Due to the reflow soldering process used in flip-chip production, self-centering takes place when the solder is melted on. As a result, the positional tolerances between the silicon chip 48 and the printed circuit board 12 in the horizontal as well as the lateral direction are very small.

Reference Symbols

| | | | |
|---|---|---|---|
| 10 | Control circuit | 50 | Silicon chip |
| 12 | Printed circuit board | 52 | Active surface |
| 14 | Output module | 54 | Circuit-board conductor |
| 16 | Component | 56 | Brazing seam |
| 18 | Control unit | 58 | Connecting leg |
| 20 | Hall-effect sensor | 60 | Housing |
| 22 | Hall-effect sensor | 62 | Housing |
| 24 | Brush holder | 64 | Soldered joint |
| 26 | Brushes | 66 | Sub-layer |
| 28 | Spring | 68 | Air gap |
| 30 | Commutator | 70 | Distance |
| 32 | Armature | | |
| 34 | Armature shaft | | |
| 36 | Worm gear | | |
| 38 | Ring magnet | | |
| 40 | Field frame | | |
| 42 | Magnet | | |
| 44 | Bearing | | |
| 46 | Positioning motor | | |
| 48 | Silicon chip | | |

1. Electronic control circuit (10) having a printed circuit board (12) on which multiple electronic components (14, 16, 18, 20, 22) are arranged, in at least one (18) of which a Hall-effect sensor (20, 22) having a circuit part (18) belonging to the control electronics is assembled, characterized in that the Hall-effect sensor (20, 22) is situated on a silicon chip (48, 50) and its active surface (52) is situated at a minimal distance (68) from a magnetic flux sensor (38) that can be moved relative to the Hall-effect sensor (20, 22).

2. Control circuit (10) according to claim 1, characterized in that the silicon chip (48) is contained in a housing (62) and is bonded with circuit-board conductors (54) of the printed circuit board (12) by way of connecting pins (58), whereby the active surface (52) of the Hall-effect sensor (20, 22) lies on the side of the silicon chip (48) facing the magnetic flux sensor (38).

3. Control circuit (10) according to claim 1, characterized in that the silicon chip (50) is bonded as a flip-chip on the printed circuit board (12), whereby the active surface (52) of the Hall-effect sensor (20, 22) is situated on the bonding side of the silicon chip (5) and faces away from the magnetic flux sensor (38).

4. Control circuit (10) according to claim 3, characterized in that the soldered joints (64) are embedded in a sub-layer (66).

5. Control circuit (10) according to one of the preceding claims, characterized in that at least two Hall-effect sensors (20, 22) are situated at a distance from each other on the silicon chip (48, 50).
